(19) United States
(12) Patent Application Publication
(10) Pub. No.: US 2024/0021753 A1
(43) Pub. Date: Jan. 18, 2024

(54) STRAIN-TUNABLE LIGHT-EMITTING DIODES FORMED USING MESA SIDEWALL EPITAXY

(71) Applicant: Meta Platforms Technologies, LLC, Menlo Park, CA (US)

(72) Inventors: Alexander TONKIKH, Wenzenbach (DE); Berthold HAHN, Hemau (DE); Michael GRUNDMANN, Kirkland, WA (US); John Joseph CURLEY, Cork (IE); Rajesh BALACHANDRAN, Cork (IE)

(21) Appl. No.: 17/863,946

(22) Filed: Jul. 13, 2022

(51) Int. Cl. H01L 33/06; H01L 33/00; H01L 33/24; H01L 33/30; H01L 33/38; H01L 33/44; H01L 33/58

(52) U.S. Cl. CPC H01L 33/06; H01L 33/0062; H01L 33/24; H01L 33/30; H01L 33/38; H01L 33/44; H01L 33/58; H01L 2933/0016; H01L 2933/0025

(57) ABSTRACT

A light-emitting diode (LED) device can include a mesa with a sidewall encompassing a first semiconductor layer, a second semiconductor layer, and an active region between the first semiconductor layer and the second semiconductor layer. The first semiconductor layer and the second semiconductor layer are oppositely doped. The active region includes a quantum well. The LED device can further include at least one epitaxial layer grown over the sidewall of the mesa. The at least one epitaxial layer comprises a semiconductor material having a wider bandgap than a semiconductor material of the quantum well and is configured to induce compressive or tensile strain in the quantum well. The compressive or tensile strain causes a bandgap of a peripheral portion of the quantum well to differ from a bandgap of a central portion of the quantum well, thereby tuning an emission profile (e.g., wavelength and/or intensity) of the LED device.

### BACKGROUND

Light-emitting diodes (LEDs) are used in many types of display devices. Smaller sized LEDs, e.g., micro-LEDs, are beneficial for certain applications such as augmented reality (AR) or virtual reality (VR). In AR/VR, the display is usually a head-mounted device. Micro-LEDs, which can be several microns or less in diameter, have the potential to provide sufficient pixel density for high resolution within the space constraints of a head-mounted device. At present, micro-LEDs tend to be significantly less efficient compared to traditional LEDs, e.g., an LED with a diameter on the order of 1 millimeter.

As the size of LEDs is reduced, efficiency losses due to surface recombination become ever more significant as a factor impacting overall performance. In particular, non-radiative recombination of charge carriers at and/or near the sidewalls of an LED mesa is a major contributor to reduced internal quantum efficiency (IQE) and reduced external quantum efficiency (EQE). In non-radiative recombination, charge carriers recombine to release phonons (heat) instead of photons. Non-radiative recombination can occur as a result of defects along the mesa sidewalls, such as dangling bonds created as a result of etching mesas from a layered semiconductor structure. Non-radiative recombination is a challenging problem for micro-LEDs because micro-LEDs tend to have a high surface to volume ratio, between the surface area of the mesa sidewalls and the volume of the micro-LED. Additionally, manufacturing processes designed for traditional LEDs are not always suitable for making micro-LEDs. Color performance (e.g., emission wavelength), device longevity, and reliability are also of concern when manufacturing micro-LEDs.

### SUMMARY

This disclosure relates generally to techniques for enhancing the efficiency of an LED through forming one or more epitaxial layers over the sidewalls of an LED mesa. The one or more epitaxial layers can be grown after performing mesa etching, through a process referred to herein as mesa sidewall epitaxy (MSE). Epitaxial layers grown using MSE may operate to reduce non-radiative recombination at or near the sidewalls. For example, the one or more epitaxial layers can include at least one layer that has a larger (wider) bandgap compared to the bandgap along a sidewall, e.g., a bandgap of a light-emitting region in the mesa.

Aspects of the present disclosure also relate to techniques for tuning the light emission characteristics of an LED through forming one or more epitaxial layers over the sidewalls of an LED mesa such that the epitaxial layer(s) induce a predetermined amount of tensile or compressive strain along the sidewalls. The techniques described herein can be applied to micro-LEDs but are also applicable to other types of LEDs.

According to certain embodiments, an LED device may include a mesa and at least one epitaxial layer grown over a sidewall of the mesa. The sidewall of the mesa encompasses a first semiconductor layer, a second semiconductor layer, and an active region between the first semiconductor layer and the second semiconductor layer. The first semiconductor layer and the second semiconductor layer are oppositely doped, and the active region includes a quantum well. The at least one epitaxial layer comprises a semiconductor material having a wider bandgap than a semiconductor material of the quantum well. The at least one epitaxial layer is configured to induce compressive or tensile strain along the sidewall, including strain in the quantum well. The compressive or tensile strain that is induced in the quantum well causes a bandgap of a peripheral portion of the quantum well to differ from a bandgap of a central portion of the quantum well.

In some examples, tensile strain in the at least one epitaxial layer induces compressive strain in the quantum well. In other examples, compressive strain in the at least one epitaxial layer induces tensile strain in the quantum well. Whether compressive or tensile, the induced strain can modify a wavelength and/or intensity of light emitted from the peripheral portion relative to the central portion. The induced strain can also cause a heavy hole band of the quantum well to diverge from a light hole band of the quantum well.

In some examples, the above-described LED device further includes a contact and a dielectric mask surrounding the contact. The contact is formed on a surface of the first semiconductor layer. The dielectric mask defines an area where the at least one epitaxial layer is absent from the first semiconductor layer.

In some examples, the at least one epitaxial layer includes an undoped epitaxial layer in contact with the active region and one or more doped epitaxial layers adjacent to the undoped epitaxial layer. For instance, the at least one epitaxial layer can include a first doped epitaxial layer in contact with the first semiconductor layer or the second semiconductor layer. As another example, the at least one epitaxial layer can include a first doped epitaxial layer that is separated from the sidewall of the mesa by the undoped epitaxial layer.

In some examples, part of the sidewall of the mesa may extend beyond another part of the sidewall while both parts are covered by the least one epitaxial layer. For instance, the active region can extend beyond the first semiconductor layer and/or the second semiconductor layer, with the at least one epitaxial layer covering the active region, the first semiconductor layer, and the second semiconductor layer.

In some examples, the at least one epitaxial layer includes an epitaxial layer having a crystal structure characterized by a lattice constant that varies as a function of distance from the sidewall of the mesa (e.g., progressively increasing or decreasing with distance).

According to certain embodiments, a method of forming an LED device involves etching a semiconductor structure to form a mesa with a sidewall encompassing a first semiconductor layer, a second semiconductor layer, and an active region between the first semiconductor layer and the second semiconductor layer. The method further involves growing at least one epitaxial layer over the sidewall of the mesa. The first semiconductor layer and the second semiconductor layer are oppositely doped. The active region includes a quantum well. The at least one epitaxial layer comprises a semiconductor material having a wider bandgap than a semiconductor material of the quantum well. The at least one epitaxial layer is configured to induce compressive or tensile strain in the quantum well. The compressive or tensile strain causes a bandgap of a peripheral portion of the quantum well to differ from a bandgap of a central portion of the quantum well.

In some examples, growing the at least one epitaxial layer involves controlling growth conditions to vary a lattice constant of the at least one epitaxial layer. Alternatively or additionally, growing the at least one epitaxial layer can involve forming an undoped epitaxial layer in contact with the active region, and forming one or more doped epitaxial layers adjacent to the undoped epitaxial layer.

In some examples, the above-described method further involves cleaning the sidewall of the mesa prior to growing the at least one epitaxial layer. The cleaning can include applying a cleaning agent to chemically remove impurities or etch damage from the sidewall.

In some examples, the above-described method further involves forming a dielectric mask over the first semiconductor layer prior to cleaning the sidewall. The dielectric mask defines an area where the at least one epitaxial layer is absent from the first semiconductor layer. The dielectric mask also operates to protect the first semiconductor layer during the cleaning of the sidewall and the growing of the at least one epitaxial layer. In some examples, the above-described method further involves forming a contact on a surface of the first semiconductor layer. The contact can be formed before or after the dielectric mask. The dielectric mask can surround the contact as part of the LED device.

In some examples, the above-described method further involves controlling a temperature at which the at least one epitaxial layer is grown such that dopants in the first semiconductor layer or the second semiconductor layer diffuse to a target depth.

### BRIEF DESCRIPTION OF THE DRAWINGS

Illustrative embodiments are described in detail below with reference to the following figures.

FIG. 1 illustrates an example of a light-emitting diode (LED).

FIG. 2 illustrates an example of an LED according to some embodiments.

FIG. 3A illustrates various stages of an example process for creating an LED using a dielectric mask, according to some embodiments.

FIGS. 3B and 3C illustrate examples of processing that can be performed after forming a dielectric mask, according to some embodiments.

FIGS. 4A-4D illustrate examples of epitaxial layers grown on mesa sidewalls, according to some embodiments.

FIG. 5 shows a band diagram for a mesa sidewall without any epitaxial layers grown on the sidewall.

FIG. 6 shows a band diagram for a mesa sidewall with an epitaxial layer grown on the sidewall.

FIGS. 7A and 7B illustrate examples of strain induced along a mesa sidewall as a result of growing an epitaxial layer.

FIG. 8 shows a band diagram illustrating the effects of strain upon a mesa sidewall.

FIG. 9 shows the effect of strain on the band structure of a quantum well material.

FIGS. 10A and 10B depict wavelength profiles for an example micro-LED without any epitaxial layers grown on the mesa sidewalls.

FIGS. 11A and 11B depict wavelength profiles for an example micro-LED with an epitaxial layer grown on the mesa sidewalls.

FIGS. 12A to 12D illustrate examples of semiconductor structures with sidewall epitaxial layers, according to some embodiments.

FIG. 13 shows a flow diagram of an example process for manufacturing an LED device, according to some embodiments.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Aspects of the present disclosure relate to techniques for enhancing the efficiency of an LED through forming one or more epitaxial layers over the sidewalls of an LED mesa. The one or more epitaxial layers can be grown through mesa sidewall epitaxy (MSE). Epitaxial layers grown using MSE may operate to reduce non-radiative recombination at or near the sidewalls. For example, the one or more epitaxial layers can include at least one layer that has a larger bandgap compared to the bandgap along a sidewall, e.g., a bandgap of a light-emitting region in the mesa. In some embodiments, the one or more epitaxial layers can include an undoped (intrinsic) semiconductor layer adjacent to a sidewall, possibly in combination with one or more doped layers. The one or more epitaxial layers may operate to prevent migration (e.g., lateral diffusion) of charge carriers toward the sidewall surface. In this manner, charge carriers may be largely confined to the active (light-emitting) region, where the charge carriers can radiatively recombine within the active region.

Aspects of the present disclosure also relate to techniques for tuning the light emission characteristics of an LED through forming one or more epitaxial layers over the sidewalls of an LED mesa such that the epitaxial layer(s) induce a predetermined amount of tensile or compressive strain along the sidewalls. The strain may be configured to modify the wavelength of light emitted at or near the sidewalls, thereby producing an LED with a particular wavelength profile. Alternatively or additionally, the strain may be configured to modify the intensity of the light emitted at or near the sidewalls. In some embodiments, an LED may include an optical element (e.g., a collimating lens) positioned at a light exit surface of the LED and that is configured based on a light emission profile (e.g., wavelength or intensity) of the LED.

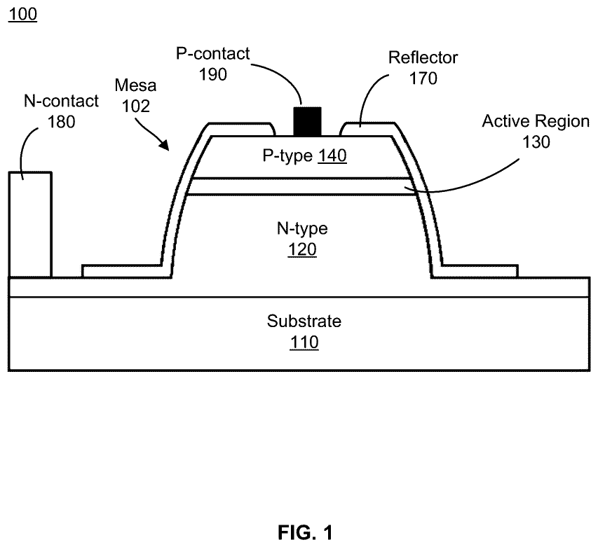

FIG. 1 illustrates an example of an LED 100. The LED 100 includes a mesa 102 formed from a semiconductor structure. The semiconductor structure can include multiple layers of semiconductor materials, such as a semiconductor layer 120, a semiconductor layer 140, and one or more layers that form an active region 130. The active region 130 may be configured to emit incoherent light and can include one or more quantum wells (QWs). In general, a quantum well is a stacked semiconductor structure comprising a layer of narrower bandgap material (a QW layer) situated between a pair of wider bandgap layers (quantum barrier (QB) layers). The QW layer is sufficiently thin such that charge carriers within the QW layer (e.g., injected holes or electrons) are quantum mechanically confined under the influence of the QB layers. Typically, quantum confinement occurs along one direction (e.g., the direction in which the layers are stacked). However, the embodiments disclosed herein are not so limited, and the QW layer need not be configured to contribute to quantum confinement. A quantum well layer in an LED constructed according to an embodiment disclosed herein can range in thickness, and the thicknesses of both the quantum well layer and the quantum barrier layers may vary depending on implementation. Additionally, in some embodiments, the active region may be a multiple quantum well (MQW) region that includes two or more quantum well layers, e.g., a first QB layer, a first QW layer, a second QB layer, a second QW layer, and a third QB layer, in that order.

LED 100 may be a micro-LED having a lateral dimension, or diameter, of less than 100 micrometers (e.g., under 10 micrometers). The semiconductor structure of the LED 100 may be made of inorganic materials. For example, the semiconductor structure may include multiple layers of III-V semiconductor materials. A III-V semiconductor material may include one or more Group III elements, such as aluminum (Al), gallium (Ga), or indium (In), in combination with a Group V element, such as nitrogen (N), phosphorus (P), arsenic (As), or antimony (Sb).

The semiconductor structure of the LED 100 may be manufactured by growing multiple epitaxial layers on a substrate, in one or more chambers, using techniques such as molecular beam epitaxy (MBE), metalorganic vapor-phase epitaxy (MOVPE), also known as organometallic vapor-phase epitaxy (OMVPE) or metalorganic chemical vapor deposition (MOCVD), or physical vapor deposition (PVD), such as pulsed laser deposition (PLD). The semiconductor layers may be grown layer-by-layer on a substrate 110 having a certain crystal lattice orientation, such as an aluminum oxide (Al₂O₃, commonly known as sapphire), gallium nitride (GaN), gallium arsenide (GaAs), monocrystalline silicon (Si), germanium (Ge), or gallium phosphide (GaP) substrate. Other semiconductor materials may also be suitable for use in forming the substrate 110. The substrate 110 may be cut in a specific direction to expose a specific plane as the growth surface.

The semiconductor layer 120 may be the first layer to be epitaxially grown on the substrate 110. Semiconductor layer 120 may include a Group III-V material, such as GaN, and may be p-doped (e.g., with Mg, Ca, Zn, or Be) or n-doped (e.g., with Si or Ge) to form a p-type semiconductor layer or an n-type semiconductor layer, respectively. In the example shown in FIG. 1, layer 120 is an n-type semiconductor layer. The active region 130 may include one or more layers grown on semiconductor layer 120. For example, the active region 130 may include one or more indium gallium nitride (InGaN) layers, one or more aluminum indium gallium phosphide (AlInGaP) layers, or one or more GaN layers, which may form one or more heterostructures, such as one or more quantum wells.

The semiconductor layer 140 may be epitaxially grown on the active region 130. Semiconductor layer 140 may include a III-V material, such as GaN, and may be p-doped (e.g., with Mg, Ca, Zn, or Be) or n-doped (e.g., with Si or Ge). In the example shown in FIG. 1, semiconductor layer 140 is a p-type semiconductor layer. Semiconductor layer 120 and semiconductor layer 140 sandwich the active region 130. For example, LED 100 may include a layer of InGaN situated between a layer of p-type GaN doped with magnesium and a layer of n-type GaN doped with silicon or germanium. In some embodiments, LED 100 may include a layer of AlInGaP situated between a layer of p-type AlInGaP doped with zinc or magnesium and a layer of n-type AlInGaP doped with selenium, silicon, or tellurium.

To make electrical contact with the semiconductor layer 120 (e.g., an n-GaN layer) of the diode and to more efficiently extract light emitted by the active region 130, the semiconductor layers may be etched to expose semiconductor layer 120 and form a mesa structure (the mesa 102) that includes the layers 120 and 130 as well as the layers of the active region 130. The mesa structure may confine carriers within the injection area of the device. Etching the mesa structure may lead to the formation of mesa sidewalls—also referred to herein as facets—that may be non-parallel with the main crystallographic directions, or in some cases, orthogonal to the growth planes.

A reflective layer 170 may be formed on the sidewalls of the mesa structure. Reflective layer 170 may include an oxide layer, such as a silicon dioxide (SiO₂) layer, and may act as a reflector to reflect emitted light out of LED 100. A contact 180, which may comprise a metal, such as Al, Au, Ni, Ti, or any combination thereof, or a non-metal conductive material, shown as an n-contact in this figure, may be formed on semiconductor layer 120 and may act as an electrode of LED 100. In addition, another contact 190, such as an Al/Ni/Au metal layer, shown as a p-contact in this figure, may be formed to make ohmic contact with semiconductor layer 140 and to act as another electrode of LED 100.

When a voltage signal is applied across the contacts 180 and 190, electrons and holes may be injected into and recombine in the active region 130, and the recombination of electrons and holes may result in emission of photons, i.e., light. The wavelength and energy of the emitted photons may depend on the energy bandgap between the valence band and the conduction band in the active region 130. For example, InGaN active layers may emit green or blue light, while AlInGaP active layers may emit red, orange, yellow, or green light. The emitted photons may be reflected by the reflective layer 170 and may exit the LED 100, for example, from the bottom side (e.g., through the substrate 110). In some implementations, one or more optical elements (e.g., lenses or waveguides) may be disposed on a light exit surface of the LED 100 to further control the light emission of the LED 100. For example, a collimating lens may be formed on the substrate 110 to collimate light that is emitted from the active region 130.

In the example of FIG. 1, the LED 100 has a parabolic mesa. Although the mesa 102 is shown as being parabolic, in some embodiments, an LED may include a mesa of another shape, such as a planar, vertical, conical, or semi-parabolic, and where a base area of the mesa may be circular, rectangular, hexagonal, or triangular. For example, in some embodiments, an LED may include a mesa with a curved shape (e.g., paraboloid shape) or a non-curved shape (e.g., conic shape). The mesa may be truncated or non-truncated.

Additionally, although FIG. 1 shows only a single LED, it will be understood that an LED device may include multiple LEDs, e.g., a one-dimensional or two-dimensional array of LEDs, where each LED in the array corresponds to an individual mesa. Further, in some implementations, two or more LEDs in the same array may share a contact (e.g., a shared n-contact and/or a shared p-contact). The LEDs in an LED array may be formed from a shared semiconductor structure, e.g., a stack of semiconductor layers on a substrate. The LEDs may be formed through etching the shared semiconductor structure into a plurality of mesas with voids or trenches between adjacent mesas. In the example of a micro-LED with a lateral dimension of less than 10 micrometers, the void or trench between mesas may be in the range of 0.05 to 7 micrometers in width, with a variety of pitch distances (e.g., center-to-center distance between adjacent mesas) being possible. The number of mesas along a first dimension may be in the thousands, and the number of mesas along a second dimension may also be in the thousands. Just as an example, an array may comprise 1,500 mesas by 1,000 mesas. In another example, an array may comprise 2,000 mesas by 1,500 mesas.

Surface imperfections on the facets of each mesa may contribute to undesirable surface recombination that decreases the efficiency of each LED. At the mesa facets, the atomic lattice structure of the semiconductor material ends abruptly. At these surfaces, atoms of the semiconductor material lack neighbors to which bonds may be attached. This results in “dangling bonds,” which are characterized by unpaired valence electrons. These dangling bonds create energy levels (quantized energy states) within the bandgap of the semiconductor material that otherwise would not exist, causing non-radiative electron-hole recombination at or near the surface of the semiconductor material.

The effects of non-radiative recombination are especially pronounced as the physical size of an LED mesa is reduced to diameters of 10 micrometers and below, especially 5 microns and below. In larger LEDs, e.g., LEDs with a diameter greater than 50 micrometers, the LED area affected by non-radiative surface recombination is relatively small. For example, assuming a diffusion length of 1 micrometer, the effects of non-radiative surface recombination may be limited to those areas within approximately 1 micrometer of the mesa facets. For an LED having a diameter of 50 micrometers, only a small fraction of the interior of the LED is within 1 micrometer of the LED's surface—i.e., mesa facet. Therefore, even though much of the surface recombination activity in an LED occurs within the quantum well layer(s), the LED areas affected by non-radiative surface recombination would not include a significant portion of the active region. By contrast, in a much smaller LED, e.g., 2 micrometers in diameter, the area affected by surface recombination may be quite significant. In such a case, a large percentage of recombination activity may correspond to non-radiative surface recombination near the mesa facets. Thus, micro-LEDs are particularly susceptible to reduced efficiency in comparison to traditional LEDs, e.g., LEDs with diameters of several millimeters.

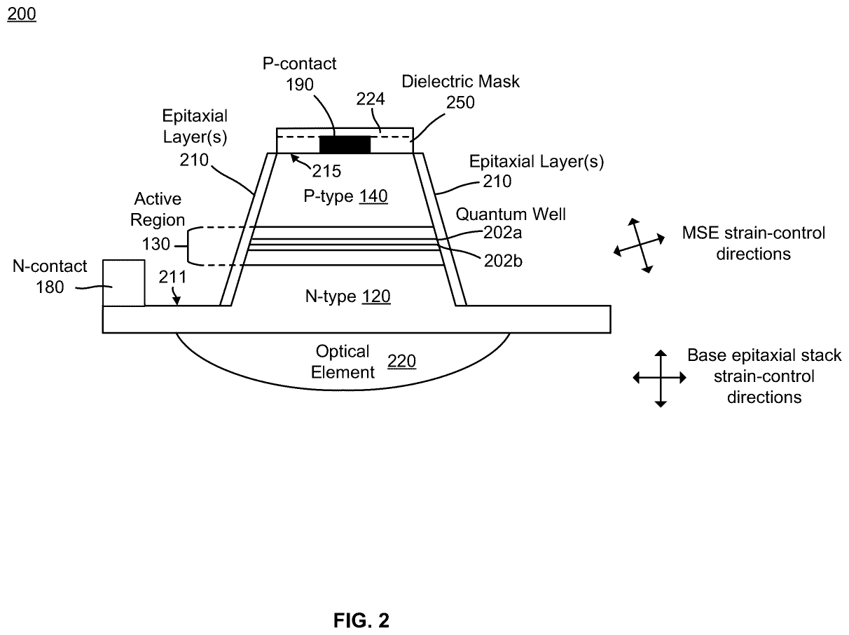

FIG. 2 illustrates an example of an LED 200, according to some embodiments. The LED 200 includes components described above with respect to the LED 100 in FIG. 1. For example, FIG. 2 shows the LED 200 as including the semiconductor layers 120 and 140 and the active region 130. The LED 200 further includes the n-contact 180 and p-contact 190. In the example of FIG. 2, the active region 130 is an MQW region with multiple quantum wells, e.g., a first QW 190a and a second QW 190b. Each quantum well corresponds to a heterostructure formed by a quantum well layer between a pair of quantum barrier layers. The quantum well layer includes a semiconductor material that has a narrower bandgap than the bandgap of the semiconductor material forming the quantum barriers. In the case of an active region that has multiple quantum wells, the active region can be structured as a stack of layers that alternate between quantum well material and quantum barrier material.

In addition to the components shown in FIG. 1, the LED 200 includes one or more epitaxial layers 210 formed on the sidewalls of the mesa. Although FIG. 2 is a cross-sectional view, it will be understood that the epitaxial layer(s) 210 may be formed over the entire perimeter of the mesa so that the sidewall surfaces are completely covered by the epitaxial layers. Further, although FIG. 2 shows the epitaxial layers as being limited to the sidewalls, in practice, the epitaxial layers may extend slightly beyond the top and/or bottom of the mesa. For instance, one or more epitaxial layers may extend beyond the base (bottom) of the mesa to overlap a flat portion 211 of the semiconductor layer 120. Similarly, one or more epitaxial layers may extend beyond the top of the mesa to overlap a flat portion 215 of the semiconductor layer 140. The epitaxial layer(s) 210 can be grown on the sidewalls after the mesa has been etched from the semiconductor layers 120 and 140 and the active region 130. Accordingly, the process of growing the epitaxial layer(s) 210 may be referred to as mesa sidewall epitaxy (MSE). The mesa etch may involve wet etching or dry etching and may produce defects (e.g., dangling bonds) along the etched facets, i.e., the sidewalls. As discussed above, such defects can contribute to non-radiative recombination and therefore reduced IQE or EQE.

The epitaxial layer(s) 210 are configured to minimize non-radiative recombination by at least partially reducing the migration (e.g., lateral diffusion) of charge carriers toward the sidewalls. In this regard, the epitaxial layer(s) 210 may include at least one layer of semiconductor material having a wider bandgap than a bandgap of a quantum well layer in the active region 130. Due to the wider bandgap of the epitaxial layer(s), charge carriers will quantum mechanically prefer the active region 130, e.g., being concentrated near the center of the active region instead of migrating toward the edges of the active region.

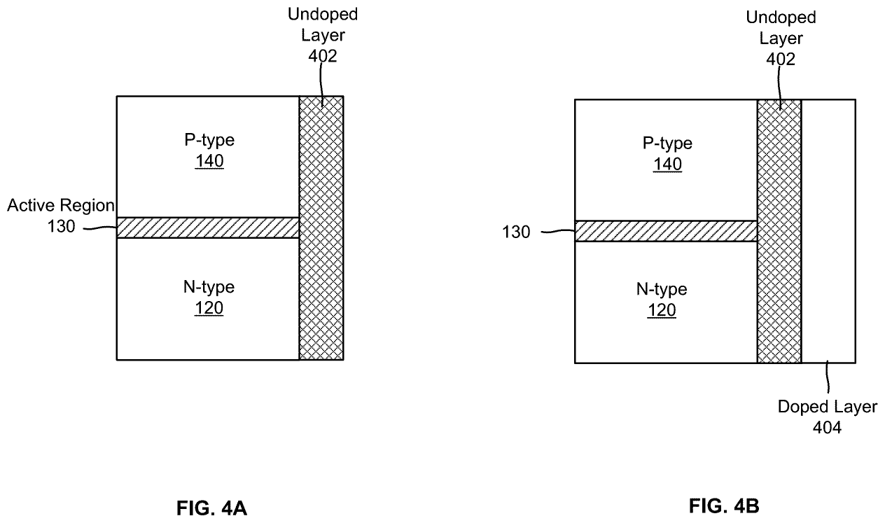

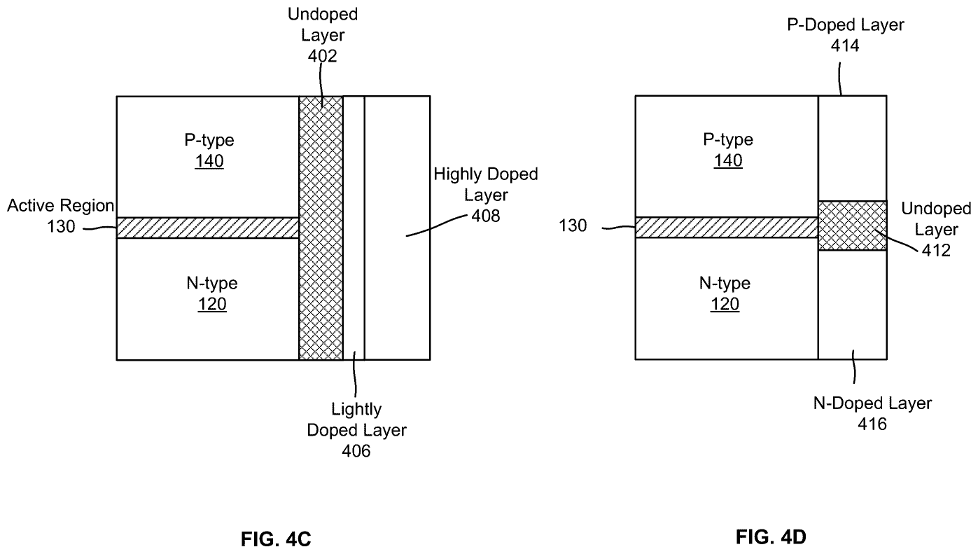

The material used for the epitaxial layer(s) 210 may also be chosen in consideration of other surrounding materials along the sidewalls. For example, if the semiconductor layers 120 and 140 are formed using InGaAlP and the quantum well layer(s) are formed using InGaP, the epitaxial layer(s) 210 may include an undoped layer of InAlP in direct contact with the sidewalls. In some embodiments, the epitaxial layer(s) include at least one layer formed using material that has a wider bandgap than the bandgaps of the semiconductor layers 120 and 140. In other words, the epitaxial layer(s) 210 may have a bandgap that is wider than the bandgap along any portion of the sidewall. Example configurations of epitaxial layers that can be formed through MSE are described below in connection with FIGS. 4A-4D.

In contrast to conventional sidewall passivation techniques such as depositing dielectric material (e.g., SiO₂) over the sidewalls, the epitaxial layer(s) 210 offer additional functionality. As described below, MSE layers can be grown with a predetermined amount of tensile or compressive strain, which induces the opposite type of strain within the mesa. The resulting strain along the sidewalls, in particular the strain along the edges of the active region 130, can influence the optical performance of the LED 200. For example, if the epitaxial layer(s) 210 are tensile-strained, the mesa sidewalls would be compressed. Conversely, if the epitaxial layer(s) 210 are compressive-strained, the sidewalls would be stretched. The strain in the epitaxial layer(s) 210 can be controlled by varying a growth parameter of each epitaxial layer 210, e.g., to achieve a larger or smaller lattice constant based on varying the ratio of precursors or, more generally, the chemical composition in an epitaxial layer.

With appropriate control over the growing conditions, the resulting strain in the epitaxial layer(s) 210 can effect a desired change in the light emission characteristics of the LED without straining the sidewalls to such an extent that the performance of the LED is adversely affected. For example, the induced strain along the sidewalls may be kept below a level associated with formation of a significant number of defects at the interface between the sidewalls and the epitaxial layer(s) 210. Thus, the structural integrity of the mesa can be maintained despite the strain applied by the epitaxial layer(s) 210. Depending on the direction and the amount of strain applied, the intensity and/or the wavelength of light emitted from the active region (e.g., around the perimeter of the LED) may be increased or decreased compared to when no epitaxial layers are formed on the sidewalls. Accordingly, the epitaxial layer(s) 210 can be used to tune an emission profile of the LED 200 in one or more dimensions, e.g., to achieve varied wavelength and/or intensity along the plane of a quantum well 202.

LED 200 may further include one or more optical elements configured to act upon (e.g., collimate) the light emitted from the active region 130. For example, LED 200 may include an optical element 220 coupled to a light exit surface of the LED. The optical element 220 may be a spherical lens, an aspherical lens, a grating, or the like. In this example, the light exit surface corresponds to a planar surface of the semiconductor layer 120. For example, the optical element 220 may be formed on the semiconductor layer 120 after removing the substrate 110 shown in FIG. 1. Light generated in the quantum wells 202 is emitted in multiple directions. Some of the light is emitted directly toward the substrate 110. Some of the emitted light may be reflected off the sidewalls of the mesa, e.g., when the sidewalls are coated with a reflective material such as the reflective layer 170 in FIG. 1. In some embodiments, the optical element 220 may be configured based on an emission profile of the LED 200. For instance, the shape (e.g., curvature) of the optical element 220 may be designed according to the color and/or intensity of light expected to be emitted in different portions of the active region 130.

In some embodiments, the one or more epitaxial layers 210 are grown after forming a dielectric mask 250 over the semiconductor layer 140. The dielectric mask 250 includes one or more dielectric materials, for example, SiO₂. The material used to form the dielectric mask 250 can be selected to withstand the environmental conditions under which the epitaxial layer(s) are grown. As such, the dielectric mask 250 may operate as a capping layer that protects the semiconductor layer 140 and any structures formed on the semiconductor layer 140 (e.g., the contact 190) during processing steps that occur as part of growing the epitaxial layer(s) 210. For example, the dielectric mask 250 may prevent the contact 190 and/or the top surface of the semiconductor layer 140 (e.g., the flat portion 215) from being damaged by a chemical agent used to “clean” the sidewalls in preparation for growing the epitaxial layer(s) 210. Additionally or alternatively, the dielectric mask 250 may prevent structural damage to the contact 190 and/or the top surface of the semiconductor layer 140 that would otherwise occur due to exposure to the relatively high temperatures typically used during epitaxy.

The dielectric mask 250 can modified or removed after the epitaxial layer(s) 210 have been formed. For example, a top portion 224 of the dielectric mask 250 may be removed, e.g., using chemical mechanical planarization (CMP), to expose the contact 190. In some embodiments, additional structures may be formed on the dielectric mask 250, including additional semiconductor materials and/or conductive materials. For example, a metal interconnect may be formed over the dielectric mask 250 to form ohmic contact with the contact 190 and to connect the contact 190 to a corresponding contact of a wafer containing a driver circuit for the LED 200. As another example, a highly doped (e.g., p⁺ or p⁺⁺) semiconductor layer may be formed through an opening in the dielectric mask 250 as an interface between the semiconductor layer 140 and the contact 190.

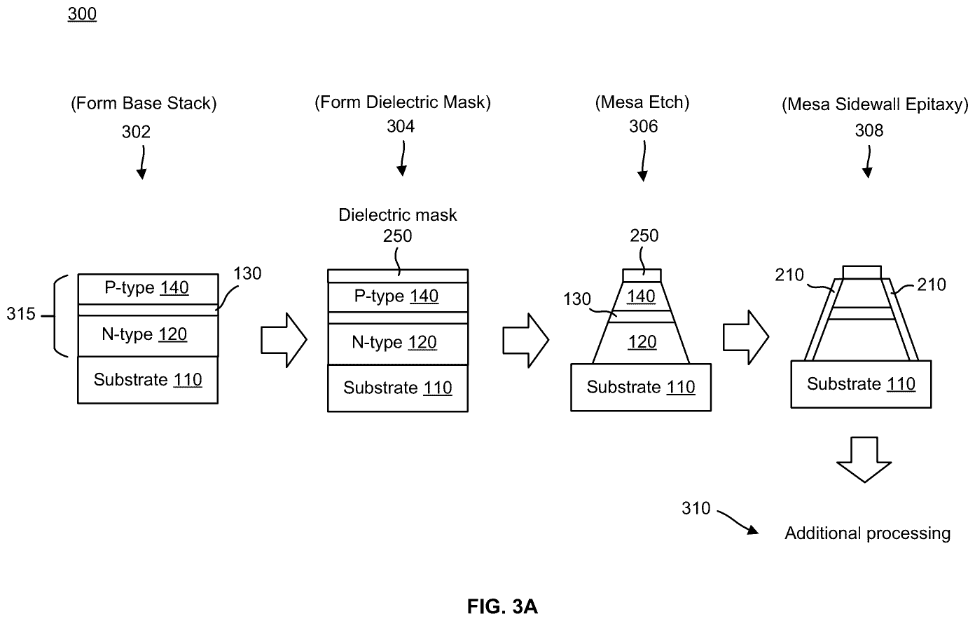

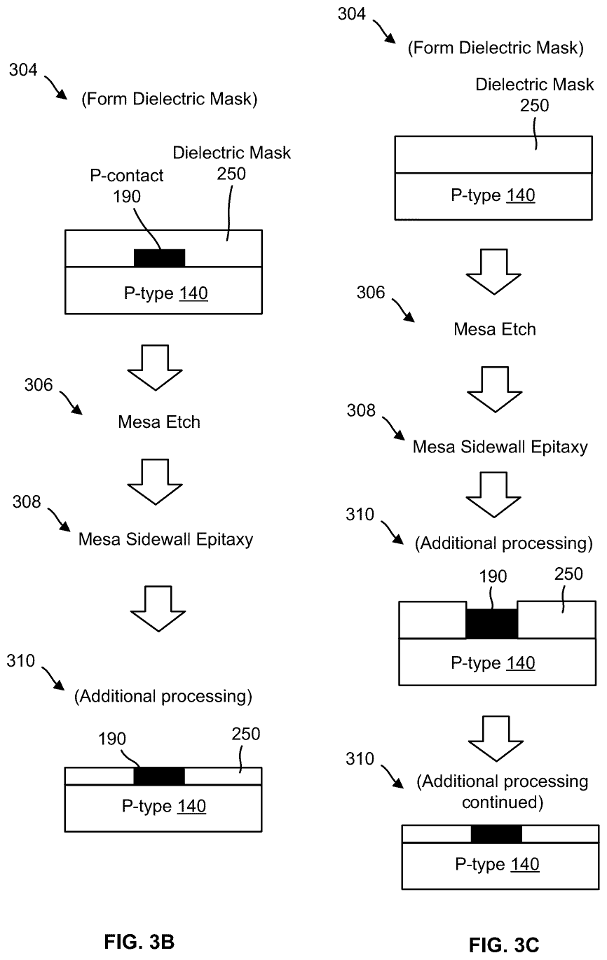

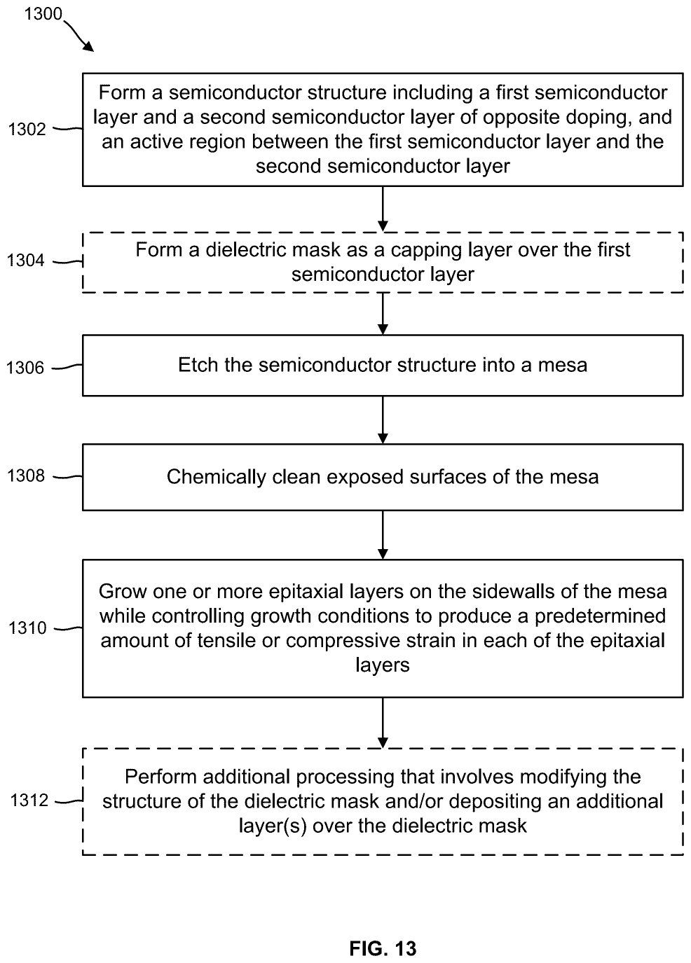

FIG. 3A illustrates various stages of an example process 300 for creating an LED using a dielectric mask, according to some embodiments. The process 300 can be performed using semiconductor manufacturing equipment including, for example, an epitaxial reactor, a chemical or physical vapor deposition system, photolithography equipment, etching equipment (wet or dry), and/or the like. Some or all of the steps in the process 300 may be performed under automated control of a computer system in communication with one or more sensors, e.g., a temperature sensor and/or a pressure sensor. The computer system performing the process 300 may include one or more processors configured to execute program instructions stored on a non-transitory computer-readable storage medium. FIG. 3A shows MSE being applied to a semiconductor structure featuring a dielectric mask. As described herein, for example, in connection with FIG. 13 below, a dielectric mask can be used to protect the underlying semiconductor material during MSE and/or during other stages not shown in FIG. 3A.

At 302, a base stack 315 is formed on top of a semiconductor substrate, e.g., the substrate 110 as shown. The base stack 315 is a layered semiconductor structure that includes an active region (e.g., the active region 130) between a pair of oppositely doped semiconductor layers (e.g., the semiconductor layers 120 and 140). The formation of the base stack 315 may involve epitaxial growth of individual layers in the base stack and doping of certain layers (e.g., the semiconductor layers 120 and 140) while leaving other layers undoped (e.g., a layer in the active region). As discussed above, the active region can include one or more QW layers. The active region may further include one or more quantum barrier (QB) layers, e.g., a first QB layer adjacent to the semiconductor layer 120 and a second QB layer adjacent to the semiconductor layer 140. When the active region has multiple quantum wells, the active region may include additional QB layers between adjacent QW layers. For simplicity, the individual layers that form the active region are omitted from FIG. 3A.

At 304, a dielectric mask (e.g., the dielectric mask 250) is formed on top of the base stack 315, over the semiconductor layer that is farthest from the substrate. In the example of FIG. 3A, the dielectric mask 250 is deposited over the semiconductor layer 140.

At 306, a mesa is formed through etching the base stack 315. The resulting mesa includes sidewalls that extend along each of the layers in the base stack. However, the base stack 315 may or may not be etched all the way through to the substrate 110. The dielectric mask 250 can be patterned prior to introducing an etching agent. The patterning of the dielectric mask 250 may involve selectively removing part of the dielectric mask to expose certain areas of the semiconductor layer 140 while keeping other areas of the semiconductor layer 140 covered.

At 308, MSE processing is performed to grow one or more epitaxial layers (e.g., epitaxial layers 210) onto the sidewalls of the mesa. These sidewall epitaxial layers can be grown one at a time and in a controlled manner to configure the resulting compressive or tensile strain that is induced at the sidewalls due to the presence of the sidewall epitaxial layers.

At 310, additional processing may be performed as part of creating the LED. The additional processing may involve one or more steps performed with respect to the dielectric mask 250, e.g., modifying the structure of the dielectric mask and/or adding material onto a surface of the dielectric mask. Examples of such processing are shown in FIGS. 3B and 3C.

FIGS. 3B and 3C illustrate examples of processing that can be performed after forming a dielectric mask, according to some embodiments. The processing in FIGS. 3B and 3C is described with reference to the operations shown in FIG. 3A and involves alternative sequences of operations that may produce similar results. In FIG. 3B, the formation of the dielectric mask (at 304) includes depositing dielectric material over a contact formed on the semiconductor layer 140 (e.g., p-contact 190). After the mesa has been etched (at 306) and one or more epitaxial layers have been grown on the sidewalls of the mesa (at 308), the additional processing (at 310) can include removal of a top portion of the dielectric mask 250 to expose the p-contact 190.

In FIG. 3C, the p-contact 190 is formed after the mesa etch and MSE, as part of the additional processing at 310. The additional processing in FIG. 3C involves forming a trench through the dielectric mask 250 and filling the trench with electrically conductive material. Once the trench has been at least partially filled with conductive material, the dielectric mask 250 can be planarized, e.g., using CMP, to set the final height of the p-contact 190 and to make the dielectric mask coplanar with the p-contact.

FIGS. 4A-4D illustrate examples of epitaxial layers grown on mesa sidewalls, according to some embodiments. The examples in FIGS. 4A-4D depict the mesa close up in order to focus on the spatial relationships between the epitaxial layers and the surrounding semiconductor layers. In FIG. 4A, an undoped layer 402 is formed on a sidewall that extends along edges of the semiconductor layer 120, the active region 130, and the semiconductor layer 120. The undoped layer 402 may have a thickness of approximately the same order of magnitude as that of the active region 130. The undoped layer 402 may include a relatively large bandgap semiconductor material, with a bandgap wider than that of the quantum well layer(s) in the active region 130. The bandgap of the undoped layer 402 may also be wider than a bandgap of the semiconductor layer 120 and/or the semiconductor layer 140.

In some embodiments, the doping profile of the semiconductor layer 120 and/or the semiconductor layer 140 can be a result of dopant diffusion when the epitaxial layer(s) are grown. For example, the semiconductor layer 140 may be doped by implanting p-type ions to a shallower depth than the ions would be implanted to in the absence of MSE. The implantation depth can be made shallower with the expectation that the ions will diffuse farther into the semiconductor layer 140 under the influence of the high temperatures in which the one or more epitaxial layers (e.g., the undoped layer 402) are grown. In this manner, a target depth for the implanted ions can be achieved taking into account any diffusion that may occur as a result of MSE processing.

In FIG. 4B, the undoped layer 402 is situated between the sidewall and a doped semiconductor layer 404. The doped semiconductor layer 404 can be p-doped or n-doped depending on the electric-field screening effect desired. For instance, the doped semiconductor layer 404 can be a highly p-doped (e.g., p⁺ or p⁺⁺) layer that limits migration of holes across the undoped layer 402. Similarly, a highly n-doped (e.g., n⁺ or n⁺⁺) layer may limit migration of electrons across the undoped layer 402. The epitaxial layers grown on the sidewall can also include layers with opposite doping, as shown in FIG. 4D.

In FIG. 4C, the sidewall layers include, in order from nearest the sidewall to farthest from the sidewall, the undoped layer 402, a lightly doped layer 406, and a highly doped layer 408. The lightly doped layer 406 and the highly doped layer 408 may be of the same doping type. For example, both layers 406, 408 may be p-doped. Additionally, as shown in the figure, the thicknesses of the sidewall layers can be different. For example, the lightly doped layer 406 may be thinner than the highly doped layer 408. The thicknesses of each of the layers 402, 406, and 408 may be of approximately the same order of magnitude as that of the active region 130. Alternatively or additionally, the total thickness of the layers 402, 406, and 408 combined may be of approximately the same order of magnitude as that of the active region 130. Alternatively or additionally, the combination of the undoped layer 402 and the doped layers 406 and 408 may be repeated multiple times, with each repeated instance featuring the same or a different ordering of the layers 402, 406, and 408. Other configurations of epitaxial layers that are grown in sequence to form a stack comprising differently doped layers (e.g., any combination of doped, undoped, oppositely doped, more doped, or less doped) are also possible. Accordingly, other implementations may feature a different sequence of epitaxial layers than that shown in FIG. 4C.

In FIG. 4D, the sidewall layers form a heterostructure in which individual layers cover different portions of the sidewall. For example, FIG. 4D shows a p-doped layer 414 adjacent to the semiconductor layer 140 and an n-doped layer 416 adjacent to the semiconductor layer 120, with an undoped layer 412 being disposed between the p-doped layer 414 and the n-doped layer 416, adjacent to the active region 130. In some embodiments, the p-doped layer 414 may be highly doped (e.g., p⁺ or p⁺⁺) relative to the semiconductor layer 140 so that holes in the semiconductor layer 140 will tend to move toward the active region 130. Similarly, the n-doped layer 416 may be highly doped (e.g., n⁺ or n⁺⁺) relative to the semiconductor layer 120 so that electrons in the semiconductor layer 120 will tend to move toward the active region 130.

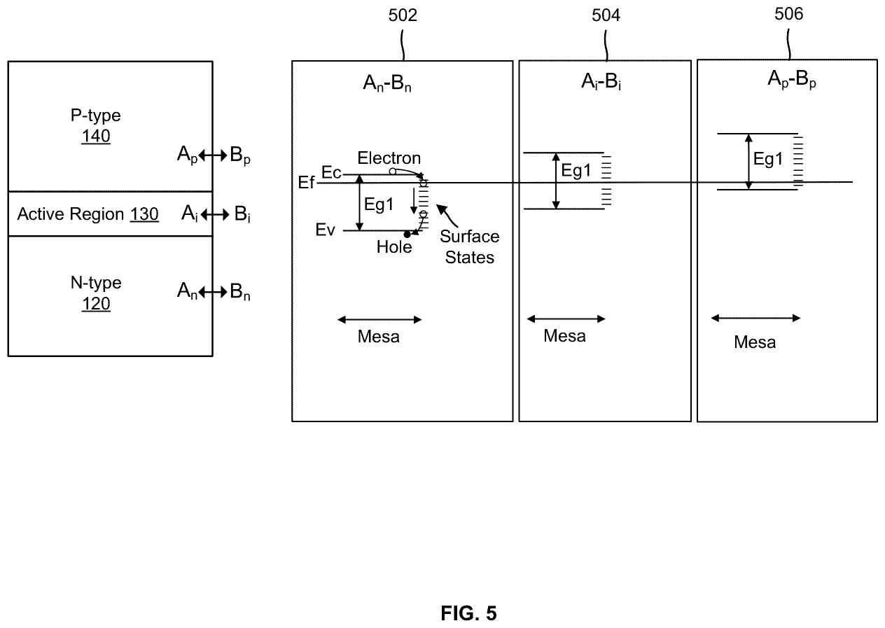

FIG. 5 shows a band diagram for a mesa sidewall without any additional epitaxial layers grown on the sidewall. The band diagram in FIG. 5 represents the state of the sidewall in the substantial absence of applied voltage, i.e., a no current or low current regime. The band diagram is divided into three regions. A first region 502 corresponds to a thin section (represented by line Aₙ-Bₚ) along the semiconductor layer 120. A second region 504 corresponds to a thin section (represented by line Aᵢ-Bᵢ) along the active region 130. A third region 506 corresponds to a thin section (represented by line Aₚ-Bₚ) along the semiconductor layer 140. In the example of FIG. 5, each of the regions 502, 504, and 506 is characterized by an identical bandgap (Eg1), although in practice, the bandgap may differ between the various layers that form a mesa. In the first region 502, the conduction band (Ec) is close to the Fermi level (Ef) and charge carriers at the surface of the sidewall are substantially free to recombine in a non-radiative manner. For example, as shown in the figure, an electron in the conduction band can move through various quantized energy states (trap levels) at the sidewall surface to non-radiatively recombine with a hole in the valence band (Ev) without releasing a photon.

The second region 504 has band energy levels characteristic of that of an intrinsic semiconductor. In particular, the conduction band and the valence band are roughly equally spaced apart with respect to the Fermi level which, in this case, corresponds to the mid-gap energy. Similar to the conduction band in the first region 502, the valence band in the third region 506 is close to the Fermi level. Although not depicted in the figure, charge carriers are also substantially free to recombine in a non-radiative manner in the second region 504 and the third region 506. For example, a hole in the third region 506 may move through quantized energy states at the sidewall surface to non-radiatively recombine with an electron in the conduction band.

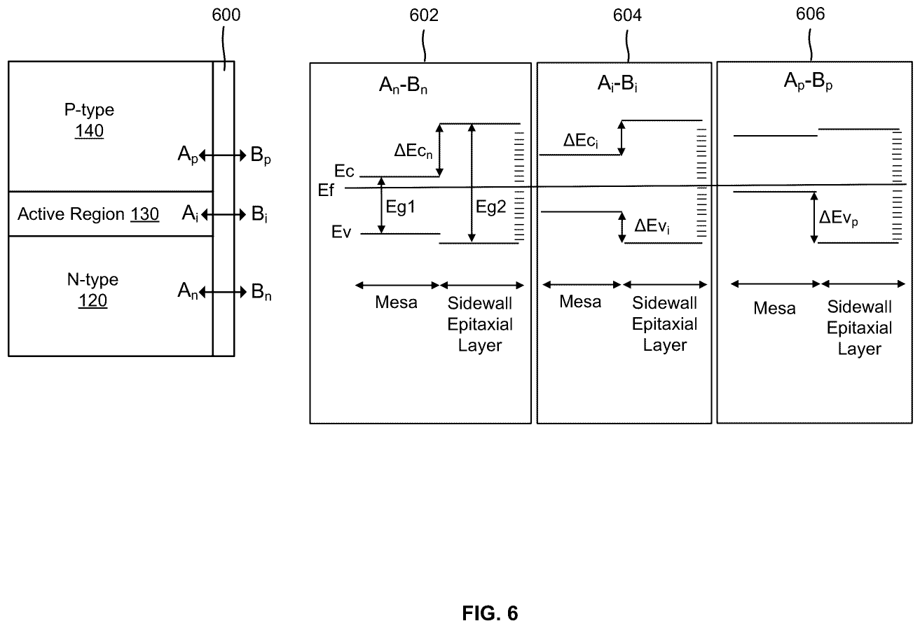

FIG. 6 shows a band diagram for a mesa sidewall with an epitaxial layer 600 grown on the sidewall. The epitaxial layer 600 may, for example, correspond to the undoped layer 402 in FIG. 4A. Like the band diagram in FIG. 5, the band diagram in FIG. 6 corresponds to a no current or low current regime. The band diagram in FIG. 6 is divided into three regions 602, 604, and 606, which are analogous to the first region 502, the second region 504, and the third region 506, respectively. In the example of FIG. 6, the regions 602, 604, 606 encompass portions of the epitaxial layer 600. As shown in the figure, the bandgap (Eg2) of the epitaxial layer 600 is significantly wider than the bandgaps of the adjacent mesa (the semiconductor layers 120 and 140 and the active region 130). That is, Eg2 is greater than Eg1. In the region 602, the difference in bandgap widths primarily involves an upward shift of the conduction band, which is higher than the conduction band in the semiconductor layer 120 by an amount ΔEcₙ. In the region 604, the difference in bandgap widths involves substantially equal-magnitude shifts (ΔEcᵢ and ΔEvᵢ) in the conduction and valence bands. In the region 606, the difference in bandgap widths primarily involves a downward shift of the valence band, which is lower than the valence band in the semiconductor layer 140 by an amount ΔEvₚ. The presence of charge carriers at or near the sidewall is significantly reduced due to the wider bandgap of the epitaxial layer 600. For instance, the epitaxial layer 600 may operate to block migration of electrons toward the sidewall area of the semiconductor layer 120. Similarly, the epitaxial layer 600 may operate to block migration of holes toward the sidewall area of the semiconductor layer 140. In the active region 130, the epitaxial layer 600 may operate to block migration of both electrons and holes. Consequently, there is little to no non-radiative recombination at or near the sidewall, unlike the configuration depicted in FIG. 5.

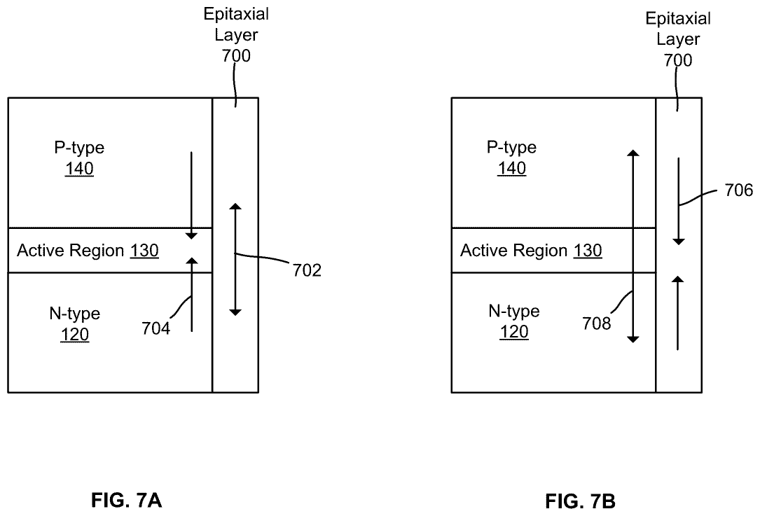

FIGS. 7A and 7B illustrate examples of strain induced along a mesa sidewall as a result of growing an epitaxial sidewall layer. In FIG. 7A, an epitaxial layer 700 is grown onto a mesa sidewall under conditions that produce tensile strain 702 in the in-plane direction, which is orthogonal to the growth direction of the epitaxial layer 700. The growth direction corresponds to the plane of the sidewall which, as shown in FIG. 2, may be oriented at an angle to the plane of a substrate on which the various layers of the mesa are grown. The epitaxial layer 700 can be grown such that the spacing in the crystal lattice of the epitaxial layer 700 becomes larger or smaller with increasing distance from the sidewall. Thus, the epitaxial layer 700 may have a crystal structure characterized by a non-uniform lattice constant that varies as a function of distance from the sidewall of the mesa. Alternatively, the epitaxial layer 700 may have a substantially uniform lattice constant that is different from that of a corresponding lattice constant along the sidewall. The epitaxial layer 700 and the sidewall can become oppositely strained so long as there is a difference between the crystal lattice of the epitaxial layer 700 and the crystal lattice of the sidewall (e.g., at the interface where the epitaxial layer 700 meets the sidewall). A crystal lattice is generally characterized by six lattice constants, sometimes referred to as lattice parameters: the lengths a, b, and c of three cell edges that meet at a vertex of a unit cell in the lattice, and the three angles α, β, and γ between the cell edges. Various growth conditions may be controlled to influence one or more of these six lattice parameters. For example, in some embodiments, a lattice constant of the epitaxial layer 700 is the result of controlling the chemical composition by varying a ratio of precursor chemicals that combine to form the epitaxial layer 700. Alternatively or additionally, the temperature and/or pressure under which the epitaxial layer 700 is grown may be controlled to influence one or more lattice constants.

Consequently, the epitaxial layer 700 in FIG. 7A may be compressive-strained in the growth direction and tensile-strained in the in-plane direction. Further, the tensile strain 702 in the in-plane direction may induce an opposite (compressive) strain 704 in the sidewall. The compressive strain 704 may be distributed along the sidewall, e.g., across the semiconductor layers 120 and 140 and the active region 130. The amount of strain needed to effect a desired change in the emission characteristics of an LED is relatively small due to the thinness of the epitaxial layers in the LED. For example, the epitaxial layer 700, the semiconductor layers 120 and 140, and the active region 130 may each be several orders of magnitude thinner (e.g., by a factor of 4) than the substrate 110. Typical thicknesses for an epitaxial layer 700 in an LED having a diameter of 1 micron may range from approximately 1 to 300 nanometers. The growth conditions of the epitaxial layer 700 can be controlled to limit the resulting strain 704 in the sidewall to below a threshold associated with plastic deformation of the sidewall and/or below a threshold associated with a significant amount of crystal defects (e.g., a threshold defect density) in the interface between the sidewall and the epitaxial layer 700.

In FIG. 7B, the epitaxial layer 700 is tensile-strained in the growth direction and compressive-strained in the in-plane direction. Compressive strain 706 of the epitaxial layer 700 in the in-plane direction may induce tensile strain 708 in the sidewall. The strain state of the epitaxial layer 700 in FIG. 7B can be achieved in a similar manner as described above with respect to FIG. 7A, through controlling growth conditions that determine one or more lattice constants of the epitaxial layer 700. Although not shown in FIGS. 7A and 7B, additional sidewall epitaxial layers can be grown with a similar type of strain as the epitaxial layer 700. When there are multiple sidewall epitaxial layers, such layers can have different strain characteristics. For example, in the configuration shown in FIG. 7A, a second epitaxial layer may be grown over the epitaxial layer 700 with the same or a different amount of tensile strain in the in-plane direction. In general, the resulting strain in each epitaxial layer grown through MSE can be controlled on a per-layer basis, e.g., through controlling the ratio of precursors such that a lattice constant is varied as the layer is being grown and/or such that the lattice constant differs from that of an adjacent layer. The extent to which each sidewall epitaxial layer contributes to the overall strain along the mesa sidewall may depend on the relative thicknesses of the sidewall epitaxial layers. Accordingly, each MSE-grown layer can be grown in a strain-controlled manner to achieve a target level of strain in the mesa sidewall. The target level of strain may depend on the type of LED being produced. For example, green micro-LEDs may benefit from longer wavelengths as a result of tensile-strained sidewall epitaxial layers.

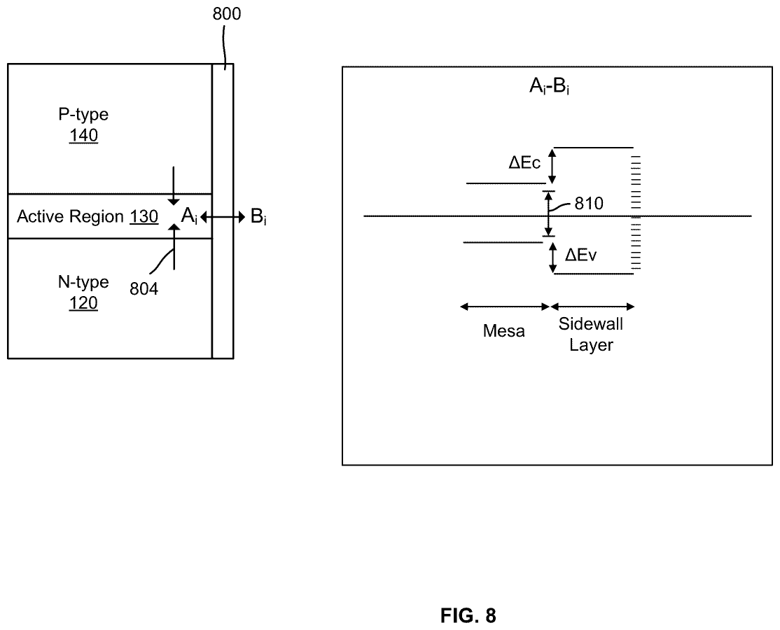

FIG. 8 shows a band diagram illustrating the effects of strain upon a mesa sidewall. In FIG. 8, an epitaxial layer 800 is undoped and is grown to be tensile-strained (in the in-plane direction, similar to FIG. 7A). The band diagram in FIG. 8 is shown for a portion of the sidewall corresponding to the active region 130. Like the band diagram in FIG. 5, the band diagram in FIG. 8 corresponds to a no current or low current regime. The tensile strain in the epitaxial layer 800 induces compressive strain 804 in the active region 130. As a result of the compressive strain 804, a bandgap 810 of a peripheral portion of one or more quantum wells in the active region 130 may become narrower in comparison to the bandgap of a central portion of the one or more quantum wells. The narrowing of the bandgap 810 corresponds to an increase in emission wavelength (red-shifted emission) at or near the sidewall. Conversely, if the epitaxial layer 800 were compressive-strained (e.g., as in FIG. 7B), the resulting tensile strain in the active region would cause the bandgap 810 to become wider, producing blue-shifted emission. The bandgaps of sidewall areas outside the quantum wells (e.g., in the semiconductor layer 120 or 140) may also be affected by the induced strain. However, since such sidewall areas are generally characterized by an indirect bandgap, no significant change in emission characteristics (e.g., little or no wavelength shift) is expected at these sidewall areas.

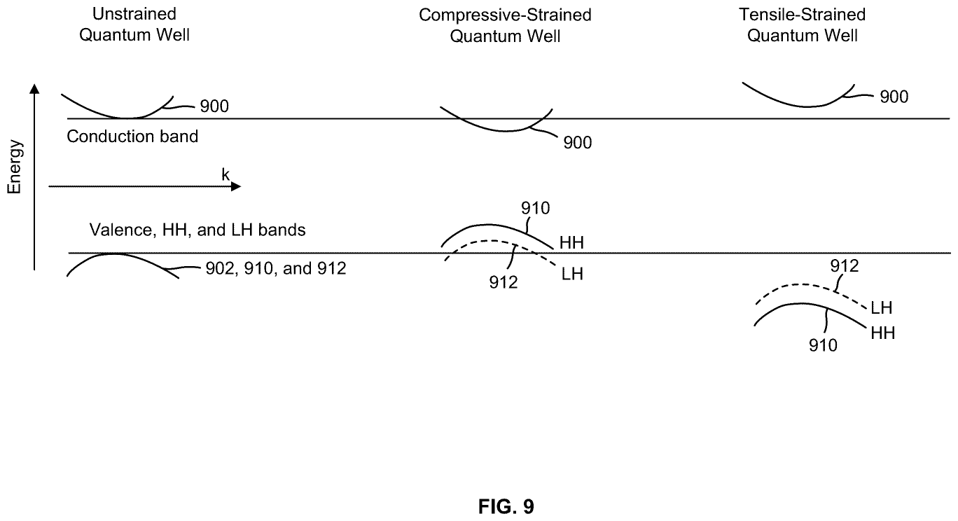

FIG. 9 shows the effect of strain on the band structure of a quantum well material. FIG. 9 depicts three possible configurations for the strain induced in the quantum well material: unstrained, compressive, and tensile. The bandgap of the quantum well material corresponds to the difference between a local minimum (gamma valley) of a conduction band 900 and a local maximum of a valence band 902. In the unstrained configuration, the valence band 902 coincides with a heavy hole (HH) band 910 and a light hole (LH) band 912.

In the compressive-strained configuration, the bandgap of the quantum well material becomes narrower relative to the unstrained configuration, due to a downward shift of the conduction band 900 and an upward shift of the HH and LH bands 910, 912.

In the tensile-strained configuration, the bandgap of the quantum well material becomes wider relative to the unstrained configuration, due to an upward shift of the conduction band 900 and a downward shift of the HH and LH bands 910, 912. Additionally, the HH band 910 is lower than the LH band 912. In contrast, the HH band 910 is higher than the LH band 912 in the compressive-strained configuration.

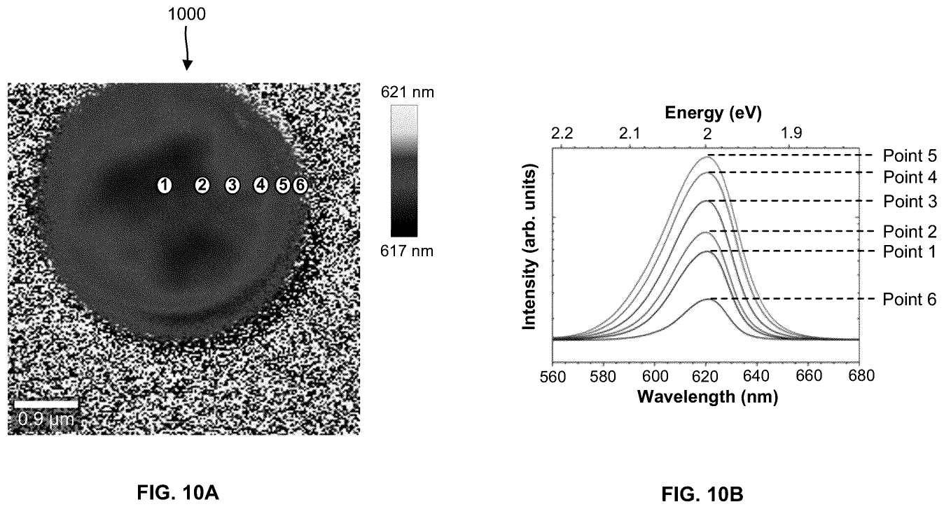

FIGS. 10A and 10B depict wavelength profiles for an example micro-LED 1000 without any epitaxial layers grown on the mesa sidewalls. The micro-LED 1000 is red-emitting and has a diameter of about 3 microns. FIG. 10A shows photoluminescence (PL) peak wavelength for the micro-LED 1000. The PL peak wavelength varies from 617-621 nanometers (nm). As shown in FIG. 10A, the wavelength is generally shorter near the center of the micro-LED and longer near the edges (along the perimeter) of the micro-LED.

FIG. 10B is a graph of PL intensity versus wavelength for each of six measurement points, labeled 1 to 6 in FIG. 10A. The PL intensity is expressed in arbitrary units. Wavelength is expressed in nanometers. FIG. 10B shows that the peak wavelength emitted at each of the six points is centered around 620 nm. FIG. 10B also shows that the intensity increases from the center toward the edges of the micro-LED (moving from point 1 to point 5) before dropping off at point 6.

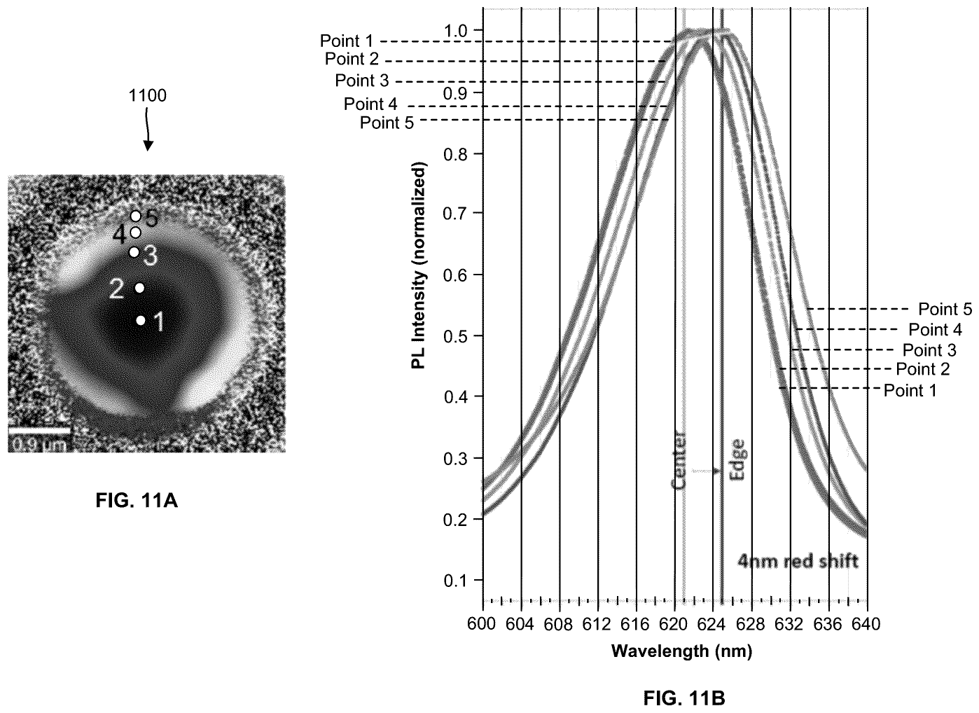

FIGS. 11A and 11B depict wavelength profiles for an example micro-LED 1100 with an epitaxial layer grown on the mesa sidewalls. The micro-LED 1100 is red-emitting and has a diameter of about 2 microns. FIG. 11A shows PL peak wavelength for the micro-LED 1100. The wavelengths emitted by the micro-LED 1100 follow a similar pattern to the wavelengths emitted by the micro-LED 1000 in FIG. 10A. However, the wavelengths are slightly longer near the edges of the micro-LED 1100 than the wavelengths near the edges of the micro-LED 1000. The longer wavelengths in FIG. 1100 are a result of red-shifted emission which, as discussed above, can be caused by a narrowing of the bandgap in the active region due to compressive strain induced by one or more epitaxial layers grown on the mesa sidewalls.

FIG. 11B is a graph of PL intensity versus wavelength for each of five measurement points, labeled 1 to 5 in FIG. 11A. As with the measurement points in FIG. 10A, the measurement points in FIG. 11A are ordered according to increasing distance from the center of the micro-LED, i.e., with point 1 being closest to the center. The emitted wavelengths follow a similar pattern to the emitted wavelengths shown in FIG. 10B. However, the wavelength curves in FIG. 11B are progressively red-shifted. For example, FIG. 11B shows the peak wavelength at the center of the micro-LED 1100 (point 1) being approximately 621 nm, and the peak wavelength at the edge of the micro-LED 1100 (point 5) being approximately 625 nm, for a maximum shift of 4 nm. In contrast, the peak wavelength is approximately the same (around 620 nm) for each of the measurement points in FIG. 10B.

In addition to a wavelength shift, the micro-LED 1100 may also be characterized by a different PL intensity in certain areas of the micro-LED. In FIG. 11B, the PL intensity is normalized to a value of 1 for all five measurement points. However, the actual intensity may be non-uniform. For example, the intensity of the micro-led 1100 may be brighter in some areas near the edge (e.g., point 5) relative to other areas near the edge (e.g., a location at the same radial distance as point 5) and/or relative to areas near the center (e.g., point 1). When injected carriers occupy narrower bandgap portions of the quantum wells, the concentration of carriers (charge carrier density) may increase in these quantum well portions, producing higher intensity emission in certain areas. Similarly, if the emitted wavelengths were shortened as a result of a widening of the bandgap at the quantum wells, blue-shifted emission may coincide with lowered PL intensity in some areas of the micro-LED.

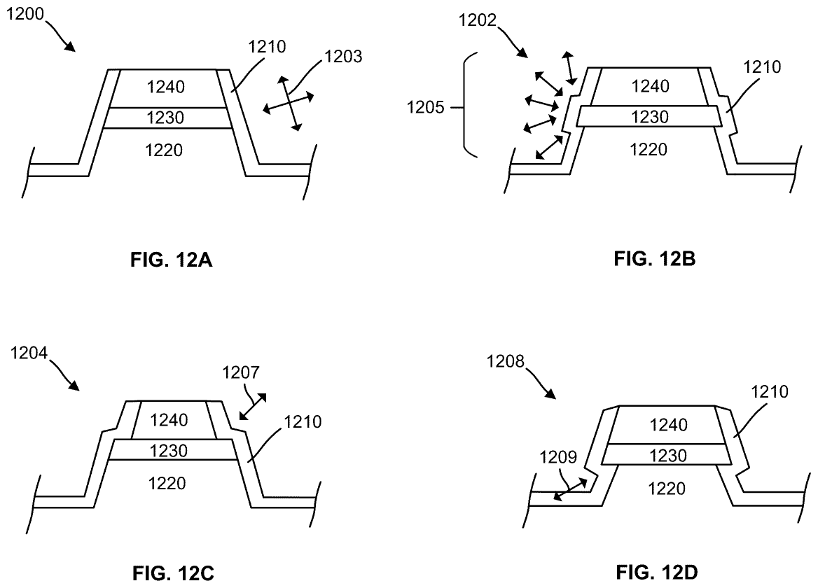

FIGS. 12A-12D illustrate examples of semiconductor structures with sidewall epitaxial layers, according to some embodiments. In FIG. 12A, a semiconductor structure 1200 includes a mesa that encompasses a first semiconductor layer 1220, a second semiconductor layer 1240, and an active region 1230 between the semiconductor layers 1220 and 1240. The semiconductor structure 1200 further includes one or more epitaxial layers 1210 formed on the sidewalls of the mesa. The semiconductor layers 1220 and 1240 may be oppositely doped (e.g., n-type and p-type, respectively). Accordingly, the semiconductor structure 1200 may correspond to the example shown in FIG. 2. FIGS. 12B, 12C, and 12D show additional semiconductor structures that can be used to form an LED.

FIG. 12B shows a semiconductor structure 1202 in which the active region 1230 overhangs the semiconductor layers 1220 and 1240. The overhang may be produced through preferentially etching the semiconductor layers 1220, 1240 during the mesa etch, e.g., using an etching agent that etches the material of the semiconductor layers 1220, 1240 at a faster rate relative to the active region 1230. Alternatively, the configuration in FIG. 12B can be produced by applying an etch mask to reduce or minimize etching of the active region 1230. The epitaxial layer(s) 1210 conform to the geometry of the sidewall. Because the active region 1230 protrudes beyond the semiconductor layers 1220 and 1240, the portions of the epitaxial layer(s) 1210 formed over the active region 1230 also protrude relative to portions of the epitaxial layers(s) 1210 formed over the semiconductor layers 1220 and 1240.

In the configuration in FIG. 12B, the epitaxial layer(s) 1210 can induce strain biaxially, along one or more of two directions 1203. The directions 1203 are shown with respect to the semiconductor structure in FIG. 12A and are analogous to the directions labeled in FIG. 2 as MSE strain-control directions. As shown in FIG. 2, the MSE strain-control directions differ from bi-axial strain directions associated with the base epitaxial stack from which the mesa is etched, i.e., the directions of any strain that may have been produced when the semiconductor layer 120, the semiconductor layer 140, and the active region 130 were grown on the substrate 110. A first of the two directions 1203 corresponds to the growth direction of the epitaxial layer(s) 1210. The other of the two directions 1203, which is orthogonal to the first direction, corresponds to the plane of the sidewall. In addition to these two directions, the epitaxial layer(s) 1210 may also induce strain along other directions 1205 along the sidewall surface. For example, the epitaxial layer(s) 1210 may be configured to induce substantially uniform tension or compression around the surfaces of the active region 1230 that protrude beyond the semiconductor layers 1220, 1240.

FIG. 12C shows a semiconductor structure 1204 in which the semiconductor layer 1240 is etched to a greater extent than the active region 1230 and the semiconductor layer 1220. The configuration in FIG. 12C can be produced by preferentially etching the semiconductor layer 1240, e.g., using an etching agent that etches a material of the semiconductor layer 1240 faster than a material of the active region 1230 and a material of the semiconductor layer 1220. Alternatively, the configuration in FIG. 12C can be produced by applying an etch mask to reduce or minimize etching of the active region 1230 and the semiconductor layer 1220.

FIG. 12D shows a semiconductor structure 1206 in which the semiconductor layer 1220 is etched to a greater extent than the active region 1230 and the semiconductor layer 1240. The configuration in FIG. 12D can be produced by preferentially etching the semiconductor layer 1220. Alternatively, the configuration in FIG. 12D can be produced by applying an etch mask to reduce or minimize etching of the active region 1230 and the semiconductor layer 1240. Similar to the configuration in FIG. 12B, the configurations in FIGS. 12C and 12D may permit strain to be induced in additional directions rather than being limited to biaxial strain. For example, tensile or compressive strain may be induced along diagonal directions 1207 (FIG. 12C) and 1209 (FIG. 12D) due to overgrowth of epitaxial material around the top of the mesa relative to the bottom of the mesa or vice versa.

The configurations in FIGS. 12A-12D may differ with respect to the band structure of a quantum well material in the active region 1230. Depending on the direction(s) in which strain is induced, the band structure of the quantum well material may also exhibit spatial variation across the surface of the active region 1230. For example, the HH and LH bands may diverge by a different amount or in opposite energy directions depending on location. Thus, strain-controlled growth of epitaxial layers can be performed in conjunction with shaping the geometry of the mesa sidewalls to tune an emission profile of an LED and/or to create a more effective barrier against carrier migration.

FIG. 13 shows a flow diagram of an example process 1300 for manufacturing an LED device, according to some embodiments. The process 1300 can be performed using semiconductor manufacturing equipment including, for example, an epitaxial reactor, a chemical or physical vapor deposition system, photolithography equipment, etching equipment (wet or dry), and/or the like. Some or all of the steps in the process 1300 may be performed under automated control of a computer system in communication with one or more sensors, e.g., a temperature sensor and/or a pressure sensor. The computer system performing the process 1300 may include one or more processors configured to execute program instructions stored on a non-transitory computer-readable storage medium.

At 1302, a semiconductor structure is formed to include a first semiconductor layer, a second semiconductor, and an active region between the first semiconductor layer and the second semiconductor. The semiconductor structure can be formed as stack of layers that are epitaxially grown in sequence on top of a substrate (e.g., the substrate 110). The first semiconductor layer and the second semiconductor are oppositely doped. For instance, the first semiconductor layer may be p-doped, and the second semiconductor layer may be n-doped, or vice versa. The active region includes at least one quantum well. In some embodiments, the active region may be an MQW structure with multiple quantum wells formed using alternating layers of quantum well material and quantum barrier material.

At 1304, a dielectric mask may optionally be formed as a capping layer over the first semiconductor layer (e.g., a p-type layer). Various dielectric materials may be suitable for use in forming the dielectric mask including, for example, SiO₂ or SiN. The dielectric mask may operate to protect the first semiconductor layer during the pre-epitaxial cleaning in block 1308 and/or during growth of one or more epitaxial layers on the sidewalls of the mesa (the MSE processing in block 1310). For example, the dielectric mask may prevent a contact region of the first semiconductor layer from being exposed to a chemical cleaning agent. Alternatively or additionally, the dielectric mask may provide thermal insulation against the relatively high temperatures used to grow the one or more epitaxial layers. In some embodiments, separate dielectric masks may be formed over contact regions in both the first semiconductor layer and the second semiconductor layer. Further, the dielectric mask may define an area where little or no growth occurs during the MSE processing. Accordingly, the dielectric mask may substantially confine the one or more epitaxial layers to being along the sidewall surfaces of the mesa.

At 1306, the semiconductor structure is etched into a mesa. The mesa etch can be performed using a wet etch process or a dry etch process. Dry etching can be used to precisely define the geometry of the mesa, which may be beneficial in some applications and depending, for example, on the sizes of the features to be formed. However, dry etching tends to introduce surface imperfections such as dangling bonds along the etched facets of the mesa. Etching may also introduce impurities such as oxide. Etch damage and impurities can be removed, at least in part, through chemical cleaning (block 1308). In some embodiments, the mesa etch in block 1306 may be performed prior to forming the dielectric mask in block 1304.

The mesa etch in block 1306 may produce a vertical mesa, a conical mesa, a parabolic mesa, or a mesa of some other shape. In general, the resulting mesa is a three-dimensional structure with sidewalls that encompass the various layers of the semiconductor structure including the first semiconductor layer, the second semiconductor layer, and the active region. The height of the mesa therefore depends on the thicknesses of the individual layers that form the semiconductor structure. As shown in the examples of FIGS. 1 and 2, the base of the mesa may extend from one of the two semiconductor layers (e.g., an n-type layer).

At 1308, exposed surfaces of the mesa are chemically cleaned to remove impurities, e.g., chemical residues leftover from the etching in block 1306 and/or oxide that develops when the etched semiconductor structure is exposed to air. The cleaning may also remove etch damage by stripping away part of the sidewall material. In this manner, the sidewall surfaces can be made more suitable for MSE. The cleaning may involve one or more chemical agents such as hydrofluoric acid (e.g., HF diluted in deionized water). In some embodiments, at least a portion of the cleaning is performed ex-situ.

At 1310, one or more epitaxial layers are grown on the sidewalls of the mesa. The one or more epitaxial layers may include an undoped layer that is in contact with all the layers along the sidewall (e.g., as shown in FIG. 4A) or an undoped layer in contact with a portion of the sidewall (e.g., centered around the active region, as shown in FIG. 4D). The one or more epitaxial layers may also include one or more doped layers (e.g., as shown in FIGS. 4B and 4C). Regardless of whether the sidewall epitaxial layers are doped or undoped, each layer of the one or more epitaxial layers may be formed using a semiconductor material that as a wider bandgap compared to a bandgap of the active region (e.g., the bandgap of a quantum well layer). In some embodiments, the QW material may comprise InGaP, and an epitaxial layer grown on a sidewall may comprise InAlP so that the transition from QW material to sidewall barrier material (the immediately adjacent epitaxial layer) involves an abrupt change in Al and/or Ga composition that produces a corresponding change in the bandgap energy (e.g., from Eg1 to Eg2 in FIG. 6). There may also be a difference in bandgap across sidewall epitaxial layers depending on the composition of the sidewall epitaxial layers. Typically, the bandgap of a doped sidewall epitaxial layer is approximately the same as that of an undoped sidewall epitaxial layer.

When growing multiple epitaxial layers on the sidewalls, the epitaxial layers can be grown sequentially under appropriate growth conditions that determine for example, the thickness, doping concentration, dopant depth, the type of strain (tensile or compressive) that develops in each epitaxial layer, and/or the amount of strain developed in each epitaxial layer. For example, the growth conditions may be controlled to vary one or more lattice constants as each epitaxial layer is individually grown (e.g., using an appropriate ratio of group III precursors), thereby producing a certain amount of strain in the epitaxial layer. As a specific example, tensile strain in an epitaxial layer (and thus compressive strain in the mesa) can be achieved by growing the epitaxial layer using a higher ratio of Al and/or In precursors compared to the same precursors used when forming the semiconductor structure from which the mesa was etched, e.g., Al and/or In precursors that form the first semiconductor layer, the second semiconductor layer, and the active region.

In some embodiments, the epitaxial growth in block 1310 can be performed such that the LED, in particular the mesa with the one or more epitaxial layers added, substantially conforms to a predetermined emission profile, e.g., so that the wavelength and/or intensity of light emitted in different portions of the active region follow a specific pattern. The emission profile may vary two-dimensionally or three-dimensionally and may be reproduced in other mesas being formed in parallel, e.g., an array of LEDs formed together on a single wafer. As described above, adding an epitaxial layer onto the sidewalls may result in the areas near the sidewall (e.g., a peripheral portion of a quantum well) having a different emission characteristic than areas farther from the sidewall (e.g., a central portion of a quantum well). As part of conforming the LED to the emission profile, one or more processing steps preceding the epitaxial growth in block 1310 may be performed taking into consideration any changes in the composition of the mesa that may occur as a result of the MSE processing. For example, doping the first semiconductor layer and/or the second semiconductor layer may involve implanting ions to a shallower depth than would otherwise be performed in the absence of MSE. In this manner, the ions implanted in the first semiconductor layer and/or the second semiconductor layer may diffuse to reach a target depth when the mesa is exposed to high temperature during the growing of the one or more epitaxial layers.

At 1312, additional processing may be performed as part of forming the LED device. Examples of such additional processing include forming electrodes (e.g., a p-contact and an n-contact), adding a reflective layer over the sidewalls (e.g., as a coating over the one or more epitaxial layers grown in block 1310), forming an optical element on a light exit surface of the LED device (e.g., the optical element 220), and bonding a wafer on which the mesa is formed to a wafer containing a driver circuit. The additional processing in block 1312 may also involve modifying the structure of the dielectric mask from block 1306 and/or depositing one or more additional layers over the dielectric mask. For example, as described above in connection with FIGS. 3A and 3B, the dielectric mask may be processed to expose a contact or to form an opening through which electrically conductive material can be deposited.

The embodiments described herein may be used in conjunction with various technologies, such as an artificial reality system. An artificial reality system, such as a head-mounted display (HMD) or heads-up display (HUD) system, generally includes a display configured to present artificial images that depict objects in a virtual environment. The display may present virtual objects or combine images of real objects with virtual objects, as in virtual reality (VR), augmented reality (AR), or mixed reality (MR) applications. For example, in an AR system, a user may view both displayed images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). In some AR systems, the artificial images may be presented to users using a light-emitting diode (LED) based display subsystem.

In some embodiments, the systems, devices, and/or components (e.g., integrated circuits or integrated circuit packages) described herein may be integrated into an HMD. For example, such an HMD may include one or more light emitters and/or one or more light sensors incorporated into a portion of a frame of the HMD such that light can be emitted toward a tissue of a wearer of the HMD that is proximate to or touching the portion of the frame of the HMD. Example locations of such a portion of a frame of an HMD may include a portion configured to be proximate to an ear of the wearer (e.g., proximate to a superior tragus, proximate to a superior auricular, proximate to a posterior auricular, proximate to an inferior auricular, or the like), proximate to a forehead of the wearer, or the like. It should be noted that multiple sets of light emitters and light sensors may be incorporated into a frame of an HMD such that a photoplethysmogram (PPG) can be determined from measurements associated with multiple body locations of a wearer of the HMD.

In the present description, for the purposes of explanation, specific details are set forth in order to provide a thorough understanding of examples of the disclosure. However, it will be apparent that various examples may be practiced without these specific details. For example, devices, systems, structures, assemblies, methods, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

Embodiments disclosed herein may be used to implement components of an artificial reality system or may be implemented in conjunction with an artificial reality system. Artificial reality is a form of reality that has been adjusted in some manner before presentation to a user, which may include, for example, a virtual reality, an augmented reality, a mixed reality, a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including an HMD connected to a host computer system, a standalone HMD, a mobile device or computing system, or any other hardware platform capable of providing artificial reality content to one or more viewers.

The methods, systems, and devices discussed above are examples. Various embodiments may omit, substitute, or add various procedures or components as appropriate. For instance, in alternative configurations, the methods described may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples that do not limit the scope of the disclosure to those specific examples.

Specific details are given in the description to provide a thorough understanding of the embodiments. However, embodiments may be practiced without these specific details. For example, well-known circuits, processes, systems, structures, and techniques have been shown without unnecessary detail in order to avoid obscuring the embodiments. This description provides example embodiments only, and is not intended to limit the scope, applicability, or configuration of the invention. Rather, the preceding description of the embodiments will provide those skilled in the art with an enabling description for implementing various embodiments. Various changes may be made in the function and arrangement of elements without departing from the spirit and scope of the present disclosure.

Also, some embodiments may be described as processes depicted as flow diagrams or block diagrams. Although each may describe the operations as a sequential process, many of the operations may be performed in parallel or concurrently. In addition, the order of the operations may be rearranged. A process may have additional steps not included in the figure. Furthermore, embodiments of the methods may be implemented by hardware, software, firmware, middleware, microcode, hardware description languages, or any combination thereof. When implemented in software, firmware, middleware, or microcode, the program code or code segments to perform the associated tasks may be stored in a computer-readable medium such as a storage medium. Processors may perform the associated tasks.

It will be apparent to those skilled in the art that substantial variations may be made in accordance with specific requirements. For example, customized or special-purpose hardware might also be used, and/or particular elements might be implemented in hardware, software (including portable software, such as applets, etc.), or both. Further, connection to other computing devices such as network input/output devices may be employed.

With reference to the appended figures, components that can include memory can include non-transitory machine-readable media. The term “machine-readable medium” and “computer-readable medium” may refer to any storage medium that participates in providing data that causes a machine to operate in a specific fashion. In embodiments provided hereinabove, various machine-readable media might be involved in providing instructions/code to processing units and/or other device(s) for execution. Additionally or alternatively, the machine-readable media might be used to store and/or carry such instructions/code. In many implementations, a computer-readable medium is a physical and/or tangible storage medium. Such a medium may take many forms, including, but not limited to, non-volatile media, volatile media, and transmission media. Common forms of computer-readable media include, for example, magnetic and/or optical media such as compact disk (CD) or digital versatile disk (DVD), punch cards, paper tape, any other physical medium with patterns of holes, a RAM, a programmable read-only memory (PROM), an erasable programmable read-only memory (EPROM), a FLASH-EPROM, any other memory chip or cartridge, a carrier wave as described hereinafter, or any other medium from which a computer can read instructions and/or code. A computer program product may include code and/or machine-executable instructions that may represent a procedure, a function, a subprogram, a program, a routine, an application (App), a subroutine, a module, a software package, a class, or any combination of instructions, data structures, or program statements.

Those of skill in the art will appreciate that information and signals used to communicate the messages described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Terms, “and” and “or” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, AB, AC, BC, AA, ABC, AAB, AABBCCC, etc.

Further, while certain embodiments have been described using a particular combination of hardware and software, it should be recognized that other combinations of hardware and software are also possible. Certain embodiments may be implemented only in hardware, or only in software, or using combinations thereof. In one example, software may be implemented with a computer program product containing computer program code or instructions executable by one or more processors for performing any or all of the steps, operations, or processes described in this disclosure, where the computer program may be stored on a non-transitory computer-readable medium. The various processes described herein can be implemented on the same processor or different processors in any combination.

Where devices, systems, components or modules are described as being configured to perform certain operations or functions, such configuration can be accomplished, for example, by designing electronic circuits to perform the operation, by programming programmable electronic circuits (such as microprocessors) to perform the operation such as by executing computer instructions or code, or processors or cores programmed to execute code or instructions stored on a non-transitory machine-readable medium, or any combination thereof. Processes can communicate using a variety of techniques, including, but not limited to, conventional techniques for inter-process communications, and different pairs of processes may use different techniques, or the same pair of processes may use different techniques at different times.

The specification and drawings are, accordingly, to be regarded in an illustrative rather than a restrictive sense. It will, however, be evident that additions, subtractions, deletions, and other modifications and changes may be made thereunto. Thus, although specific embodiments have been described, these are not intended to be limiting. Various modifications and equivalents are within the scope of the following claims.

What is claimed is:

1. A light-emitting diode (LED) device comprising:
a mesa with a sidewall encompassing a first semiconductor layer, a second semiconductor layer, and an active region between the first semiconductor layer and the second semiconductor layer; and
at least one epitaxial layer, wherein:
the first semiconductor layer and the second semiconductor layer are oppositely doped,
the active region includes a quantum well,
the at least one epitaxial layer is grown over the sidewall of the mesa and is configured to induce compressive or tensile strain in the quantum well,
the compressive or tensile strain causes a bandgap of a peripheral portion of the quantum well to differ from a bandgap of a central portion of the quantum well, and
the at least one epitaxial layer comprises a semiconductor material having a wider bandgap than a semiconductor material of the quantum well.

2. The LED device of claim 1, wherein tensile strain in the at least one epitaxial layer induces compressive strain in the quantum well.

3. The LED device of claim 1, wherein compressive strain in the at least one epitaxial layer induces tensile strain in the quantum well.

4. The LED device of claim 1, wherein the compressive or tensile strain modifies a wavelength or intensity of light emitted from the peripheral portion relative to the central portion.

5. The LED device of claim 1, wherein the compressive or tensile strain causes a heavy hole band of the quantum well to diverge from a light hole band of the quantum well.

6. The LED device of claim 1, further comprising:
a contact formed on a surface of the first semiconductor layer; and
a dielectric mask surrounding the contact, wherein the dielectric mask defines an area where the at least one epitaxial layer is absent from the first semiconductor layer.

7. The LED device of claim 1, wherein the at least one epitaxial layer comprises an undoped epitaxial layer in contact with the active region and one or more doped epitaxial layers adjacent to the undoped epitaxial layer.

8. The LED device of claim 7, wherein the one or more doped epitaxial layers comprise a first doped epitaxial layer in contact with the first semiconductor layer or the second semiconductor layer.

9. The LED device of claim 7, wherein the one or more doped epitaxial layers comprise a first doped epitaxial layer that is separated from the sidewall of the mesa by the undoped epitaxial layer.

10. The LED device of claim 1, wherein:
the active region extends beyond at least one of the first semiconductor layer or the second semiconductor layer, and
the at least one epitaxial layer covers the active region, the first semiconductor layer, and the second semiconductor layer.

11. The LED device of claim 1, wherein the at least one epitaxial layer includes a first epitaxial layer, and wherein a crystal structure of the first epitaxial layer is characterized by a lattice constant that varies as a function of distance from the sidewall of the mesa.

12. A method of forming a light-emitting diode (LED) device, the method comprising:
etching a semiconductor structure to form a mesa with a sidewall encompassing a first semiconductor layer, a second semiconductor layer, and an active region between the first semiconductor layer and the second semiconductor layer; and
growing at least one epitaxial layer over the sidewall of the mesa, wherein:
the first semiconductor layer and the second semiconductor layer are oppositely doped,
the active region includes a quantum well,
the at least one epitaxial layer is configured to induce compressive or tensile strain in the quantum well,
the compressive or tensile strain causes a bandgap of a peripheral portion of the quantum well to differ from a bandgap of a central portion of the quantum well, and
the at least one epitaxial layer comprises a semiconductor material having a wider bandgap than a semiconductor material of the quantum well.

13. The method of claim 12, wherein growing the at least one epitaxial layer comprises controlling growth conditions to vary a lattice constant of the at least one epitaxial layer.

14. The method of claim 12, wherein the compressive or tensile strain modifies a wavelength or intensity of light emitted from the peripheral portion relative to the central portion, in accordance with a predetermined emission profile.

15. The method of claim 12, wherein the compressive or tensile strain causes a heavy hole band of the quantum well to diverge from a light hole band of the quantum well.

16. The method of claim 12, further comprising:
cleaning the sidewall of the mesa prior to growing the at least one epitaxial layer, wherein the cleaning involves applying a cleaning agent to chemically remove impurities or etch damage from the sidewall.

17. The method of claim 16, further comprising:
forming a dielectric mask over the first semiconductor layer prior to cleaning the sidewall, wherein:
the dielectric mask defines an area where the at least one epitaxial layer is absent from the first semiconductor layer, and
the dielectric mask operates to protect the first semiconductor layer during the cleaning of the sidewall and the growing of the at least one epitaxial layer.

18. The method of claim 17, further comprising:
forming a contact on a surface of the first semiconductor layer, wherein:
the contact is formed before or after the dielectric mask is formed,
the dielectric mask surrounds the contact, and
the dielectric mask forms part of the LED device.

19. The method of claim 12, further comprising:
controlling a temperature at which the at least one epitaxial layer is grown such that dopants in the first semiconductor layer or the second semiconductor layer diffuse to a target depth.

20. The method of claim 12, wherein growing the at least one epitaxial layer comprises:
forming an undoped epitaxial layer in contact with the active region; and
forming one or more doped epitaxial layers adjacent to the undoped epitaxial layer.
